(19) United States
(12) Patent Application Publication
(10) Pub. No.: US 2024/0292712 A1
(43) Pub. Date: Aug. 29, 2024

(54) WINDOW AND DISPLAY DEVICE INCLUDING THE SAME

(71) Applicant: SAMSUNG DISPLAY CO., LTD., Yongin-Si (KR)

(72) Inventors: SEONGSIK CHOI, Yongin-si (KR); SUNGWOO KIM, Yongin-si (KR)

(21) Appl. No.: 18/487,734

(22) Filed: Oct. 16, 2023

(30) Foreign Application Priority Data
Feb. 27, 2023 (KR) 10-2023-0025661

(51) Int. Cl. H10K 59/80

(52) U.S. Cl. CPC H10K 59/873; H10K 59/8792

(57) ABSTRACT

Provided is a window including a base layer, a first layer disposed on the base layer, a second layer disposed on the first layer, and a third layer disposed on the second layer, and the first layer includes a compound of a first metal oxide and a second metal oxide.

### CROSS-REFERENCE TO RELATED APPLICATIONS

This U.S. non-provisional patent application claims priority under 35 U.S.C. § 119 of Korean Patent Application No. 10-2023-0025661, filed on Feb. 27, 2023, the entire contents of which are hereby incorporated by reference.

### BACKGROUND

The present disclosure herein relates to a window and a display device including the same, and more particularly, to a window having excellent mechanical characteristics, while having a low reflectance, and a display device including the same.

Display devices are used for various multimedia apparatuses such as televisions, mobile phones, tablet computers, and game consoles to provide image information to a user. Recently, a flexible display device capable of folding or bending is being developed in various forms. The flexible display device may be variously changed in shape such as folding, rolling, or bending, and may thus be easily portable.

The flexible display device may include a display panel and a window capable of folding or bending. However, there is a limitation in that the window of the flexible display device is deformed due to a folding or bending operation, or easily damaged by external impact.

### SUMMARY

The present disclosure provides a window having a low reflectance, and having excellent mechanical strength.

The present disclosure also provides a display device having improved durability and reliability while maintaining a low reflectance.

An embodiment of the inventive concept provides a window including a base layer, a first layer disposed on the base layer, a second layer disposed on the first layer, and a third layer disposed on the second layer. The first layer includes a compound of a first metal oxide and a second metal oxide.

In an embodiment, the second metal oxide may have a refractive index less than that of the first metal oxide, and the content of the second metal oxide may be greater than about 6 wt % and less than about 10 wt %.

In an embodiment, the first layer may have a thickness greater than about 50 nm and less than about 90 nm.

In an embodiment, the first metal oxide may be niobium oxide (Nb₂O₅), and the second metal oxide may be yttrium oxide (Y₂O₃).

In an embodiment, the first layer may have a refractive index greater than that of each of the base layer and the second layer, and the refractive index of the first layer may be about 1.7 to about 3.0 at a wavelength of about 550 nm.

In an embodiment, the second layer may include at least one of silicon dioxide (SiO₂), fused silica, fluorine-doped fused silica, magnesium fluoride (MgF₂), calcium fluoride (CaF₂), aluminum fluoride (AlF₃), yttrium fluoride (YF₃), ytterbium fluoride (YbF₃), aluminum oxide (Al₂O₃), or magnesium oxide (MgO).

In an embodiment, the second layer may include a compound of silicon dioxide (SiO₂) and a third metal oxide.

In an embodiment, the third metal oxide may include aluminum oxide (Al₂O₃), and the content of the third metal oxide may be about 10 wt % or less.

In an embodiment, the third layer may include a fluorine-containing polymer.

In an embodiment, the second layer may have a refractive index of about 1.3 to about 1.6 at a wavelength of about 550 nm, and the third layer may have a refractive index of about 1.3 to about 1.5 at a wavelength of about 550 nm.

In an embodiment, the second layer may have a thickness of about 10 nm to about 100 nm, and the third layer may have a thickness of about 20 nm to about 45 nm.

In an embodiment, the base layer may include a glass substrate or a polymer film.

In an embodiment, the second layer may be directly disposed on the first layer, and the third layer may be directly disposed on the second layer.

In an embodiment, at a wavelength of about 550 nm, a reflectance at an upper surface of the third layer may be about 1.0% or less.

In an embodiment, the window may further include a fourth layer disposed between the base layer and the first layer, and containing at least one of silicon dioxide (SiO₂), fused silica, fluorine-doped fused silica, magnesium fluoride (MgF₂), calcium fluoride (CaF₂), aluminum fluoride (AlF₃), yttrium fluoride (YF₃), ytterbium fluoride (YbF₃), aluminum oxide (Al₂O₃), or magnesium oxide (MgO).

In an embodiment of the inventive concept, a display device includes a display module, and a window disposed on the display module, and the window includes a base layer, a first layer disposed on the base layer, a second layer disposed on the first layer, and a third layer disposed on the second layer, the first layer containing a compound of a first metal oxide and a second metal oxide.

In an embodiment, the first metal oxide may be niobium oxide (Nb₂O₅), and the second metal oxide may be yttrium oxide (Y₂O₃).

In an embodiment, the second layer may include a compound of silicon dioxide (SiO₂) and aluminum oxide (Al₂O₃).

In an embodiment, the display module may include a base substrate, a circuit layer disposed on the base substrate, a light-emitting element layer including a light-emitting element, and disposed on the circuit layer, and an anti-reflection layer including a color filter overlapping the light-emitting element, and disposed on the light-emitting element layer.

In an embodiment, an upper surface of the third layer may define an outermost surface of the window.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a combined perspective view of a display device according to an embodiment of the inventive concept;

FIG. 1B is an exploded perspective view of a display device according to an embodiment of the inventive concept;

FIG. 2 is a cross-sectional view of a display device according to an embodiment of the inventive concept;

FIG. 3 is a cross-sectional view illustrating a portion of a display module according to an embodiment of the inventive concept; and

FIGS. 4A and 4B are cross-sectional views of a window according to an embodiment of the inventive concept.

### DETAILED DESCRIPTION

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

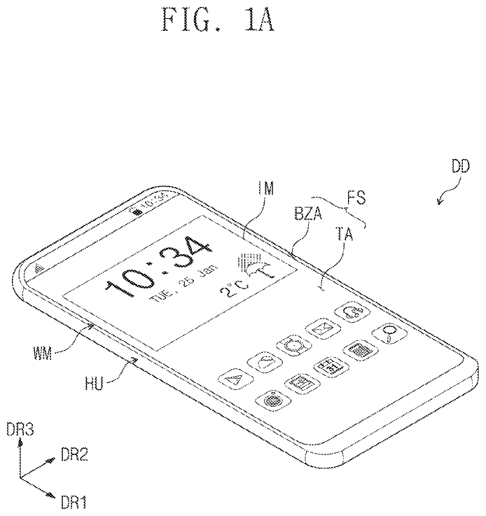

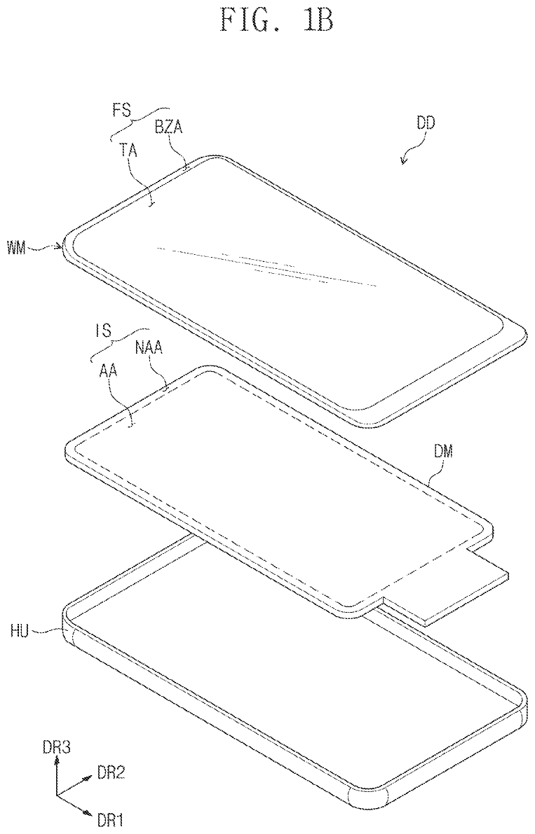

FIG. 1A is a combined perspective view of a display device according to an embodiment of the inventive concept. FIG. 1B is an exploded perspective view of a display device according to an embodiment of the inventive concept.

Referring to FIGS. 1A and 1B, a display device DD may be activated in response to electrical signals. The display device DD may display an image IM, and detect an external input. The display device DD may include various examples. For example, the display device DD may include a tablet computer, a laptop computer, a desktop computer, a smart television, etc. In an embodiment, the display device DD is exemplarily illustrated as a smartphone, but is not intended to be limited thereto.

The display device DD may display the image IM on a display surface FS parallel to a plane formed by a first direction DR1 and a second direction DR2, and facing toward a third direction DR3. The display surface FS on which the image IM is displayed may correspond to a front surface of the display device DD, and correspond to a front surface FS of a window WM. Hereinafter, the display surface and the front surface of the display device DD, and the front surface of the window WM are denoted as the same reference numeral or symbol, “FS”. The image IM may include a still image as well as dynamic image. FIG. 1A illustrates a clock and a plurality of icons as an example of the image IM.

In various embodiments, a front surface (or upper surface) and a rear surface (or lower surface) of each of the members are defined on the basis of a direction in which the image IM is displayed. The front surface and the rear surface may be opposed to each other in the third direction DR3, and the normal direction of each of the front surface and the rear surface may be parallel to the third direction DR3. A distance between the front surface and the rear surface in the third direction DR3 may correspond to the thickness of a display panel 100 in the third direction DR3.

The directions indicated by the first to third directions DR1, DR2, and DR3 are relative concepts, and may be changed to other directions. Hereinafter, the first to third directions DR1, DR2, and DR3 refer to respective directions indicated by the first to third directions DR1, DR2, and DR3, and thus are denoted as the same reference numerals or symbols. In addition, in this specification, the term “on a plane” may refer to when viewed from the third direction DR3.

The display device DD according to an embodiment of the inventive concept may detect a user's input applied from the outside. The user's input may include various types of external inputs such as a part of the user's body, light, heat, or pressure. The user's input may be provided in various forms, and the display device DD may also detect the user's input applied from a side surface or rear surface of the display device DD according to a structure of the display device DD, but is not limited to any one embodiment.

As illustrated in FIGS. 1A and 1B, the display device DD includes a window WM, a display module DM, and an outer case HU. In an embodiment, the window WM and the outer case HU are coupled together to form an exterior of the display device DD. In this embodiment, the outer case HU, the display module DM, and the window WM may be stacked in sequence along the third direction DR3.

The window WM may include an optically transparent material. The window WM may include an insulation panel. For example, the window WM may be made of glass, plastic, or a combination thereof.

The front surface FS of the window WM, as previously described, defines the front surface of the display device DD. A transmission region TA may be an optically transparent region. For example, the transmission region TA may be a region having a visible light transmittance of about 90% or more.

A bezel region BZA may be a region having a relatively lower light transmittance than the transmission region TA. The bezel region BZA defines a shape of the transmission region TA. The bezel region BZA may be adjacent to the transmission region TA, and may surround the transmission region TA.

The bezel region BZA may have a predetermined color. The bezel region BZA may cover a peripheral region NAA of the display module DM, and block the peripheral region NAA from being visible to the outside. In various embodiments, and the bezel region BZA may be omitted from the window WM according to an embodiment of the inventive concept.

The display module DM may display the image IM and detect an external input. The image IM may be displayed on a front surface IS of the display module DM. The front surface IS of the display module DM includes an active region AA and a peripheral region NAA. The active region AA may be activated in response to electrical signals.

In this embodiment, the active region AA may be a region on which the image IM is displayed, and at the same time, a region on which the external input is detected. The transmission region TA of the window WM can overlap at least the active region AA of the display module DM. For example, the transmission region TA can overlap the entire surface of the active region AA or at least a portion thereof. The transmission region TA may be smaller than the active region AA, such that the peripheral region NAA is not viewable through the transmission region TA. Accordingly, a user may view the image IM through the transmission region TA, or provide external inputs therethrough. In various embodiments, the image IM can be displayed in a first region and an external input can be detected in a second region separate from the first region. The active region AA, however, is not limited to any one embodiment.

The peripheral region NAA may be a region covered by the bezel region BZA, where the bezel region BZA can block the view of the peripheral region NAA. The peripheral region NAA is adjacent to the active region AA. The peripheral region NAA may surround the active region AA, where the peripheral region NAA can wrap around the outer edge of the display module DM. A driving circuit or driving wires for driving the active region AA may be disposed in the peripheral region NAA.

The display module DM may include a display panel and a sensor layer. The image IM may be displayed substantially on the display panel, and the external input may be detected substantially on the sensor layer. Since the display module DM includes both of the display panel and the sensor layer, the display module DM may display the image IM and detect the external input at the same time. Details thereof will be described later.

The display device DD according to an embodiment may further include a driving circuit. The driving circuit may include a flexible circuit board and a main circuit board. The flexible circuit board may be electrically connected to the display module DM. The flexible circuit board may connect the display module DM to the main circuit board. However, this is exemplarily illustrated, and the flexible circuit board according to an embodiment of the inventive concept may not be connected to the main circuit board, and the flexible circuit board may be a rigid substrate.

The flexible circuit board may be connected to pads of the display module DM disposed in the peripheral region NAA. The flexible circuit board may provide electrical signals to the display module DM for driving the display module DM. The electrical signals may be generated in the flexible circuit board, or in the main circuit board. The main circuit board may include various driving circuits for driving the display module DM, connectors for a power supply, or the like. The main circuit board may be connected to the display module DM through the flexible circuit board.

FIG. 1B exemplarily illustrates the display module DM in an unfolded state, but at least a portion of the display module DM may be bendable. In this embodiment, a portion of the display module DM may be bendable toward the rear surface of the display module DM, and the portion bent toward the rear surface may be a portion to which the main circuit board is connected. Accordingly, the main circuit board may be assembled overlapping the rear surface of the display module DM.

The outer case HU can be coupled to the window WM to define the exterior of the display device DD. The outer case HU provides a predetermined inner space that can have a volume configured to house the display module DM, where the display module DM may be accommodated in the inner space.

The outer case HU may include a material having relatively high rigidity. For example, the outer case HU may include a plurality of frames and/or plates composed of glass, plastic, metal, or a combination thereof. The outer case HU may stably protect components of the display device DD, which are accommodated in the inner space, from external impact.

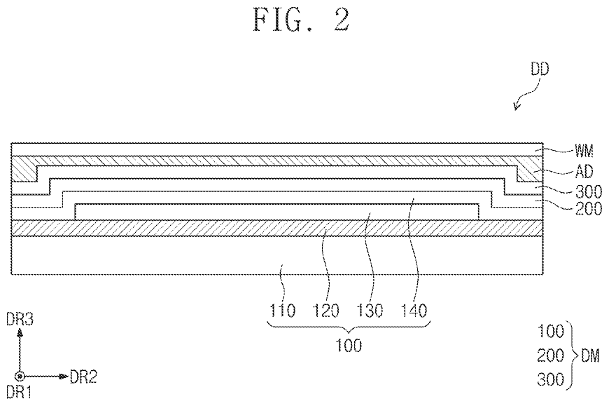

FIG. 2 is a cross-sectional view of a display device according to an embodiment of the inventive concept.

Referring to FIG. 2, the display device DD may include a display module DM and a window WM. The display module DM and the window WM may be bonded to each other by an adhesive layer AD. In the display device DD, according to an embodiment, the display module DM may include a display panel 100, a sensor layer 200, and an anti-reflection layer 300. Among the plurality of layers included in the display module DM, the anti-reflection layer 300 may be bonded to the window WM through the adhesive layer AD, where the adhesive layer can be transparent to allow the display panel 100 to be visible.

The display panel 100 may be a component that substantially generates images. The display panel 100 may be an emission-type display panel, where for example, the display panel 100 may be an organic light-emitting display (OLED) panel, an inorganic light-emitting display panel, a micro-LED display panel, or a nano-LED display panel. The display panel 100 may be referred to as a display layer.

The display panel 100 may include a base substrate 110, a circuit layer 120, a light-emitting element layer 130, and an encapsulation layer 140.

The base substrate 110 may be a member that provides a base surface on which the circuit layer 120 is disposed. The base substrate 110 may be a rigid substrate, or a flexible substrate capable of bending, folding, rolling, etc. The base substrate 110 may be a glass substrate, a metal substrate, or a polymer substrate. However, an embodiment of the inventive concept is not limited thereto, and the base substrate 110 may be an inorganic layer, an organic layer, or a composite material layer.

The base substrate 110 may have a multi-layer structure. For example, the base substrate 110 may include a first synthetic resin layer, a multi-layer or single-layer inorganic layer, and a second synthetic resin layer disposed on the multi-layer or single-layer inorganic layer. The first and second synthetic resin layers may each include a polyimide-based resin, but an embodiment of the inventive concept is not particularly limited thereto.

The circuit layer 120 may be disposed on the base substrate 110. The circuit layer 120 may include an insulation layer, a semiconductor pattern, a conductive pattern, a signal line, and the like.

The light-emitting element layer 130 may be disposed on the circuit layer 120. The light-emitting element layer 130 may include a light-emitting element, where for example, the light-emitting element may include an organic light-emitting material, an inorganic light-emitting material, an organic-inorganic light-emitting material, quantum dots, quantum rods, a micro-LED, or a nano-LED. The light-emitting element layer 130 may include light-emitting regions that can form pixels (picture elements).

The encapsulation layer 140 may be disposed on the light-emitting element layer 130. The encapsulation layer 140 may protect the light-emitting element layer 130 from moisture, oxygen, or foreign substances such as dust particles, where the encapsulation layer 140 can be transparent. The encapsulation layer 140 may include at least one inorganic layer. The encapsulation layer 140 may include a stacked structure of inorganic layer/organic layer/inorganic layer.

The sensor layer 200 may be disposed on the display panel 100. The sensor layer 200 may detect an external input applied from the outside. The external input may be a user's input. The user's input may include various types of external inputs such as a part of the user's body, light, heat, a pen, or pressure.

The sensor layer 200 may be formed on the display panel 100 through a continuous process. In this case, the sensor layer 200 may be directly disposed on the display panel 100. Herein, to be “directly disposed” may mean that there is no intervening component disposed between the sensor layer 200 and the display panel 100. For example, there may be no separate adhesive member disposed between the sensor layer 200 and the display panel 100.

The anti-reflection layer 300 may be directly disposed on the sensor layer 200. The anti-reflection layer 300 may reduce the reflectance of external light incident from the outside of the display device DD, where this may reduce screen glare. The anti-reflection layer 300 may be formed on the sensor layer 200 through a continuous process. The anti-reflection layer 300 may include color filters. The color filters may have a predetermined arrangement. For example, the color filters may be arranged in consideration of light-emitting colors of pixels included in the display panel 100. In addition, the anti-reflection layer 300 may further include a black matrix adjacent to the color filters. Detailed description of the anti-reflection layer 300 will be made later.

According to an embodiment of the inventive concept, the sensor layer 200 may be omitted. In this case, the anti-reflection layer 300 may be directly disposed on the display panel 100. According to an embodiment of the inventive concept, the positions of the sensor layer 200 and the anti-reflection layer 300 may be switched.

According to an embodiment of the inventive concept, the display device DD may further include an optical layer disposed on the anti-reflection layer 300. For example, the optical layer may be formed on the anti-reflection layer 300 through a continuous process. The optical layer may control a direction of light incident from the display panel 100, and improve the front luminance of the display device DD. For example, the optical layer may include an organic insulation layer on which openings are defined respectively corresponding to light-emitting regions of the pixels included in the display panel 100, and a high-refractive layer which covers the organic insulation layer, and which is filled in the openings. The high-refractive layer may have a higher refractive index than that of the organic insulation layer.

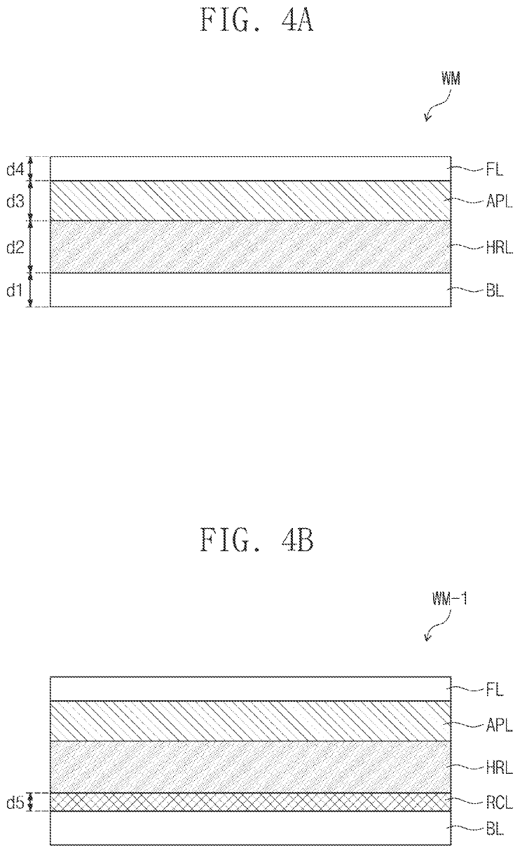

The window WM may provide a front surface of the display device DD. The window WM may include a glass film or synthetic resin film as a base film. The window WM may further include functional layers such as an anti-reflection layer or anti-fingerprint layer, where the window WM can include multiple layers. The functional layers included in the window WM will be described in detail with reference to FIGS. 4A and 4B. The window WM may further include a bezel pattern overlapping the aforementioned bezel region BZA (see FIG. 1B).

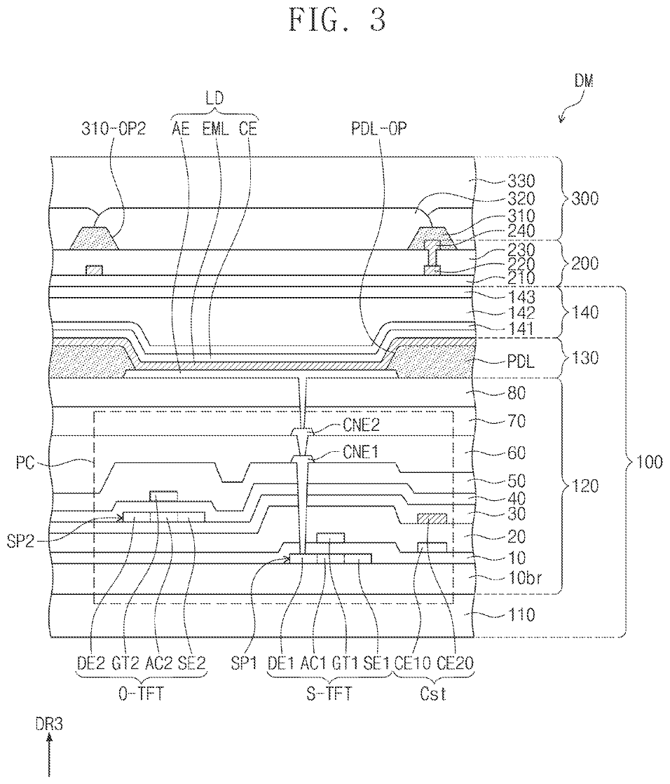

FIG. 3 is a cross-sectional view illustrating a portion of a display module DM according to an embodiment of the inventive concept. FIG. 3 illustrates a cross-section of one light-emitting element LD and a portion of a pixel circuit PC included in the display module DM.

A display panel 100 included in the display module DM according to an embodiment may include a base substrate 110. The base substrate 110 may be a member that provides a base surface on which a circuit layer 120 can be disposed. The base substrate 110 may be a glass substrate, a metal substrate, a plastic substrate, a silicon substrate, or the like. However, an embodiment of the inventive concept is not limited thereto, and the base substrate 110 may be an inorganic layer, an organic layer, or a composite material layer.

A buffer layer 10br may be disposed on the base substrate 110. The buffer layer 10br may prevent metal atoms or impurities from diffusing from the base substrate 110 to a first semiconductor pattern SP1 thereabove. The first semiconductor pattern SP1 includes a channel region AC1 of a silicon transistor S-TFT. The buffer layer 10br may control the heat delivery rate during a crystallization process for forming the first semiconductor pattern SP1, so that the first semiconductor pattern SP1 may be formed uniformly.

The first semiconductor pattern SP1 may be disposed on the buffer layer 10br. The first semiconductor pattern SP1 may include a silicon semiconductor. For example, the silicon semiconductor may include amorphous silicon, polycrystalline silicon, single crystal silicon, or the like. For example, the first semiconductor pattern SP1 may include low-temperature polysilicon.

FIG. 3 illustrates only a portion of the first semiconductor pattern SP1 disposed on the buffer layer 10br, however the first semiconductor pattern SP1 may further be disposed in other regions. The first semiconductor pattern SP1 may be arranged across pixels in a particular rule. The first semiconductor pattern SP1 may have different electrical properties depending on whether the first semiconductor pattern SP1 is doped or is not doped. The first semiconductor pattern SP1 may include a first region having high conductivity, and a second region having low conductivity. The first region may be doped with an N-type dopant or a P-type dopant. A P-type transistor may include a doped region doped with a P-type dopant, and an N-type transistor may include a doped region doped with an N-type dopant. The second region may be an undoped region, or a doped region doped with a lower concentration than the first region.

The first region may have a higher conductivity than the second region, and the first region may substantially serve as an electrode or signal line. The second region may substantially correspond to an active region (or channel) of a transistor. In other words, a portion of the first semiconductor pattern SP1 may be an active region of a transistor, another portion may be a source or drain of the transistor, and another portion may be a connection electrode or connection signal line.

A source region SE1 (or source), a channel region AC1 (or channel), and a drain region DE1 (or drain) of the silicon transistor S-TFT may be formed from the first semiconductor pattern SP1. The source region SE1 and the drain region DE1 may extend in opposite directions from the channel region AC1 on a cross-section.

In various embodiments, a back metal layer may be disposed under each of the silicon transistor S-TFT and an oxide transistor O-TFT. The back metal layer may be disposed overlapping the pixel circuit PC (indicated by the dashed box), and may block external light from reaching the pixel circuit PC. The back metal layer may be disposed between the base substrate 110 and the buffer layer 10br. Alternatively, the back metal layer may be disposed between a second insulation layer 20 and a third insulation layer 30. The back metal layer may include reflective metal. For example, the back metal layer may include silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), p+ doped amorphous silicon, and the like. The back metal layer may be connected to an electrode or wiring, and may receive a constant voltage or signals therefrom. According to an embodiment of the inventive concept, the back metal layer may be a floating electrode in the form of being isolated from other electrodes or wiring. According to an embodiment of the inventive concept, an inorganic barrier layer may be further disposed between the base substrate 110 and the buffer layer 10br.

The first insulation layer 10 may be disposed on the buffer layer 10br. The first insulation layer 10 may overlap a plurality of pixels in common, and cover the first semiconductor pattern SP1. The first insulation layer 10 may be an inorganic layer and/or organic layer, and may have a single-layer or multi-layer structure, where the first insulation layer 10 can include an electrically insulating material. The first insulation layer 10 may include at least one of aluminum oxide, titanium oxide, silicon oxide, silicon nitride, silicon oxynitride, zirconium oxide, or hafnium oxide. In an embodiment, the first insulation layer 10 may be a silicon oxide layer as a single layer. Not only the first insulation layer 10, but also an insulation layer of the circuit layer 120 to be described later may be an inorganic layer and/or organic layer, and may have a single-layer or multi-layer structure. The inorganic layer may include at least one of the aforementioned materials, but an embodiment of the inventive concept is not limited thereto.

A gate GT1 of the silicon transistor S-TFT can be disposed on the first insulation layer 10. The gate GT1 may be a portion of a metal pattern. The gate GT1 overlaps the channel region AC1. The gate GT1 may serve as a mask during a doping process of the first semiconductor pattern SP1 to form the source region SE1 and a drain region DE1. The gate GT1 may include titanium (Ti), silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), indium tin oxide (ITO), indium zinc oxide (IZO), etc., but an embodiment of the inventive concept is not limited particularly thereto.

The second insulation layer 20 may be disposed on the first insulation layer 10, and may cover the gate GT1, where the second insulation layer 20 can include an electrically insulating material. The third insulation layer 30 may be disposed on the second insulation layer 20, where the third insulation layer 30 can include an electrically insulating material. A second electrode CE20 of a storage capacitor Cst may be disposed between the second insulation layer 20 and the third insulation layer 30. In addition, a first electrode CE10 of the storage capacitor Cst may be disposed between the first insulation layer 10 and the second insulation layer 20.

A second semiconductor pattern SP2 may be disposed on the third insulation layer 30. The second semiconductor pattern SP2 may include a channel region AC2 of the oxide transistor O-TFT to be described later. The second semiconductor pattern SP2 may include an oxide semiconductor. The second semiconductor pattern SP2 may include a transparent conductive oxide (TCO) such as indium tin oxide (ITO), indium zinc oxide (IZO), indium gallium zinc oxide (IGZO), zinc oxide (ZnO), or indium oxide (In₂O₃).

The oxide semiconductor may include a plurality of regions distinguished according to whether the transparent conductive oxide has been reduced or not. A region where the transparent conductive oxide is reduced (hereinafter, reduced region) has a higher conductivity than a region where the transparent conductive oxide is not reduced (hereinafter, unreduced region). The reduced region substantially serves as a source/drain of a transistor or a signal line. The unreduced region substantially corresponds to a semiconductor region (or active region or channel) of the transistor. In other words, one partial region of the second semiconductor pattern SP2 may be the semiconductor region of the transistor, another partial region may be the source/drain region of the transistor, and another partial region may be a signal transmission region.

A source region SE2 (or source), a channel region AC2 (or channel), and a drain region DE2 (or drain) of the oxide transistor O-TFT may be formed from the second semiconductor pattern SP2. The source region SE2 and the drain region DE2 may extend in opposite directions from the channel region AC2 on a cross-section.

The fourth insulation layer 40 may be disposed on the third insulation layer 30, where the fourth insulation layer 40 can include an electrically insulating material. The fourth insulation layer 40 may overlap a plurality of pixels in common, and cover the second semiconductor pattern SP2. Although not illustrated in the drawing, the fourth insulation layer 40 may overlap a gate GT2 of the oxide transistor O-TFT, and may be provided in the form of an insulation pattern that exposes the source region SE2 and the drain region DE2 of the oxide transistor O-TFT.

The gate GT2 of the oxide transistor O-TFT is disposed on the fourth insulation layer 40. The gate GT2 of the oxide transistor O-TFT may be a portion of a metal pattern. The gate GT2 of the oxide transistor O-TFT may overlap the channel region AC2.

A fifth insulation layer 50 may be disposed on the fourth insulation layer 40, and may cover the gate GT2, where the fifth insulation layer 50 can include an electrically insulating material. A first connection electrode CNE1 may be disposed on the fifth insulation layer 50. The first connection electrode CNE1 may be connected to the drain region DE1 of the silicon transistor S-TFT through a contact hole passing through the first to fifth insulation layers 10, 20, 30, 40, and 50.

A sixth insulation layer 60 may be disposed on the fifth insulation layer 50, where the sixth insulation layer 60 can include an electrically insulating material. A second connection electrode CNE2 may be disposed on the sixth insulation layer 60. The second connection electrode CNE2 may be connected to the first connection electrode CNE1 through a contact hole passing through the sixth insulation layer 60. A seventh insulation layer 70 may be disposed on the sixth insulation layer 60, and may cover the second connection electrode CNE2, where the seventh insulation layer 70 can include an electrically insulating material. An eighth insulation layer 80 may be disposed on the seventh insulation layer 70, where the eighth insulation layer 80 can include an electrically insulating material.

The sixth insulation layer 60, the seventh insulation layer 70, and the eighth insulation layer 80 may each be an organic layer. For example, the sixth insulation layer 60, the seventh insulation layer 70, and the eighth insulation layer 80 may each include a general-purpose polymer such as benzo cyclobutene (BCB), polyimide, hexamethyldisiloxane (HMDSO), polymethylmethacrylate (PMMA), or polystyrene (PS), a polymer derivative with a phenol-based group, an acrylate-based polymer, an imide-based polymer, an aryl ether-based polymer, an amide-based polymer, a fluorine-based polymer, a p-xylene-based polymer, a vinyl alcohol-based polymer, a blend thereof, and the like.

A light-emitting element LD may include a first electrode AE (or pixel electrode), a light-emitting layer EML, and a second electrode CE (or common electrode). The light-emitting layer EML and the second electrode CE may each be formed across a plurality of pixels in common.

The first electrode AE of the light-emitting element LD may be disposed on the eighth insulation layer 80. The first electrode AE of the light-emitting element LD may be a (semi) transparent electrode or a reflective electrode. According to an embodiment of the inventive concept, each of the first electrodes AE of the light-emitting element LD may include a reflection layer formed of Ag, Mg, Al, Pt, Pd, Au, Ni, Nd, Ir, Cr, or a compound thereof, and a transparent or semitransparent electrode layer formed on the reflection layer. The transparent or semitransparent electrode layer may include at least one material selected from the group consisting of indium tin oxide (ITO), indium zinc oxide (IZO), indium gallium zinc oxide (IGZO), zinc oxide (ZnO) or indium oxide (In₂O₃), and aluminum-doped zinc oxide AZO. For example, the first electrode AE of the light-emitting element LD may include a stacked structure of ITO/Ag/ITO.

Pixel-defining films PDL may be disposed on the eighth insulation layer 80, where the pixel-defining films PDL can be on opposite sides of the first electrode AE. The pixel-defining films PDL may include a uniform material and may be formed through a uniform process. The pixel-defining films PDL may have light-absorbing characteristics, and for example, the pixel-defining films PDL may have a black color. The pixel-defining films PDL may include a black coloring agent. The black coloring agent may include a black dye or black pigment. The black coloring agent may include carbon black, metal such as chrome, or an oxide thereof. The pixel-defining films PDL may correspond to light-blocking patterns having light-blocking characteristics.

The pixel-defining film PDL may cover a portion of the first electrode AE of the light-emitting element LD. For example, an opening PDL-OP that exposes a portion of the first electrode AE of the light-emitting element LD may be defined in the pixel-defining film PDL. The pixel-defining film PDL may increase a distance between an edge of the first electrode AE and the second electrode CE of the light-emitting element LD. Therefore, the pixel-defining film PDL may serve to prevent arcing, etc. generated on the edge of the first electrode AE.

In various embodiments, a hole control layer may be disposed between the first electrode AE and the light-emitting layer EML. The hole control layer may include a hole transport layer, and may further include a hole injection layer. An electron control layer may be disposed between the light-emitting layers EML and the second electrode CE. The electron control layer may include an electron transport layer, and may further include an electron injection layer. The hole control layer and the electron control layer may be formed across a plurality of pixels in common using an open mask.

An encapsulation layer 140 may be disposed on the light-emitting element layer 130. The encapsulation layer 140 may include an inorganic layer 141, an organic layer 142, and an inorganic layer 143 that are stacked in sequence, but the layers constituting the encapsulation layer 140 are not limited thereto.

The inorganic layers 141 and 143 may protect the light-emitting element layer 130 from moisture and oxygen, and the organic layer 142 may protect the light-emitting element layer 130 from foreign substances such as dust particles. The inorganic layers 141 and 143 may each include a silicon nitride layer, a silicon oxynitride layer, a silicon oxide layer, a titanium oxide layer, an aluminum oxide layer, or the like. The organic layer 142 may include an acrylate-based organic layer, but an embodiment of the inventive concept is not limited thereto.

A sensor layer 200 may be disposed on the display panel 100, where the sensor layer 200 may be on the encapsulation layer 140. The sensor layer 200 may be referred to as a sensor, an input-sensing layer, or an input-sensing panel. The sensor layer 200 may include a sensor base layer 210, a first conductive layer 220, a sensing insulation layer 230, and a second conductive layer 240.

The sensor base layer 210 may be directly disposed on the display panel 100, where the sensor base layer 210 may be directly on the inorganic layer 143. The sensor base layer 210 may be an inorganic layer including at least one of silicon nitride, silicon oxynitride, or silicon oxide. Alternatively, the sensor base layer 210 may be an organic layer including an epoxy resin, an acrylate resin, or an imide-based resin. The sensor base layer 210 may have a single-layer structure, or a structure of multiple layers stacked along a third direction DR3.

The first conductive layer 220 and the second conductive layer 240 may each have a single-layer structure, or a structure of multiple layers stacked along the third direction DR3. The first conductive layer 220 and the second conductive layer 240 may include conductive lines that define a sensing electrode in a meshed form. The conductive lines may not overlap the opening PDL-OP and may overlap the pixel-defining films PDL. The first conductive layer 220 and the second conductive layer 240 may be vertically stacked, where the second conductive layer 240 can be in electrical contact with the first conductive layer 220. The first conductive layer 220 and the second conductive layer 240 may be vertically aligned with a portion of the pixel-defining films PDL.

The single-layer structure of the first or second conductive layer 220, 240 may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), or indium zinc tin oxide (IZTO). In addition, the transparent conductive layer may include a conductive polymer such as PEDOT, metal nanowires, graphene, etc.

The multi-layer structure of the first or second conductive layer 220, 240 may include metal layers. The metal layers may have, for example, a three-layer structure of titanium/aluminum/titanium. The multi-layer structure of the first or second conductive layer 220, 240 may include at least one metal layer and at least one transparent conductive layer.

The sensing insulation layer 230 may be disposed between the first conductive layer 220 and the second conductive layer 240. The sensing insulation layer 230 may include an inorganic film. The inorganic film may include at least one of aluminum oxide, titanium oxide, silicon oxide, silicon nitride, silicon oxynitride, zirconium oxide, or hafnium oxide.

Alternatively, the sensing insulation layer 230 may include an organic film. The organic film may include at least one of an acrylate-based resin, a methacrylate-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

An anti-reflection layer 300 may be disposed on the sensor layer 200. The anti-reflection layer 300 may include a light-blocking pattern 310, color filters 320, and a planarization layer 330.

The anti-reflection layer 300 may decrease an external light reflectance. The anti-reflection layer 300 may include the color filters 320. The color filters 320 may be provided in plurality, and the plurality of color filters 320 may be disposed in a predetermined arrangement in consideration of light-emitting colors of pixels included in the display panel 100. Meanwhile, in the display module DM according to an embodiment, the anti-reflection layer 300 may not include a retarder and a polarizer, and may increase the reflectance of the display module DM through the color filters 320. In the display module DM according to an embodiment, the anti-reflection layer 300 may not include a polarizing film or a polarizing layer.

The material constituting the light-blocking pattern 310 is not particularly limited as long as absorbing light. In an embodiment, the light-blocking pattern 310, which is a layer having a black color, may include a black coloring agent. The black coloring agent may include a black dye or black pigment. The black coloring agent may include carbon black, metal such as chrome, or an oxide thereof.

The light-blocking pattern 310 may cover the second conductive layer 240 of the sensor layer 200. The light-blocking pattern 310 may prevent external light reflection caused by the second conductive layer 240. The light-blocking pattern 310 may overlap a portion of the pixel-defining film PDL.

A split opening 310-OP2 may be defined in the light-blocking pattern 310. The split opening 310-OP2 may overlap at least a portion of the first electrode AE of the light-emitting element LD. The color filters 320 may each overlap the corresponding first electrode AE of the light-emitting element LD. The plurality of color filters 320 may each cover the corresponding split opening 310-OP2. The plurality of color filters 320 may each be in contact with the light-blocking pattern 310.

The planarization layer 330 may cover the light-blocking pattern 310 and the plurality of color filters 320. The planarization layer 330 may include an organic material, and provide a flat surface on an upper surface of the planarization layer 330. According to an embodiment of the inventive concept, the planarization layer 330 may be omitted.

FIGS. 4A and 4B are cross-sectional views of a window according to an embodiment of the inventive concept.

Referring to FIG. 4A, a window WM according to an embodiment of the inventive concept includes a window base layer BL, a first layer HRL, a second layer APL, and a third layer FL. In the window WM according to an embodiment, the window base layer BL, the first layer HRL, the second layer APL, and the third layer FL may be stacked in sequence.

The window base layer BL may include a transparent material. In an embodiment, the window base layer BL may include a glass substrate or a polymer film. In an embodiment, the window base layer BL may be a chemically strengthened glass substrate. In the case where the window base layer BL is a chemically strengthened glass substrate, the window base layer BL may have increased mechanical strength, compared to an un-strengthened glass substrate, while having a small thickness, so that the window base layer BL may be used for a window of a foldable display device. In the case where the window base layer BL includes a polymer film, the window base layer BL may include a polyimide (PL) film or a polyethylene terephthalate (PET) film. The window base layer BL of the window WM may have a multi-layer or single-layer structure. For example, the window base layer BL may have a structure in which a plurality of polymer films are coupled together through an adhesive member, or may have a structure in which the glass substrate and the polymer film are coupled to each other through an adhesive. The window base layer BL may be made of a flexible material.

The window base layer BL may have a thickness d1 of, for example, about 20 μm to about 60 μm. Desirably, the thickness d1 of the window base layer BL may be about 20 μm to about 40 μm. FIG. 4A exemplarily illustrates that the window base layer BL has a rectangular shape in cross-section. However, an embodiment of the inventive concept is not limited thereto, and the window base layer BL according to an embodiment may have a shape in which an upper surface thereof has a rounded edge due to a curved surface. More particularly, the window base layer BL may have a shape in which an upper surface overlapping the bezel region BZA (see FIG. 1B) has a rounded edge due to a curved surface.

The first layer HRL may be disposed on the window base layer BL. In this embodiment, the first layer HRL may be directly disposed on the window base layer BL. The first layer HRL may be in contact with the window base layer BL.

The first layer HRL may be a layer having a higher refractive index than the window base layer BL. The first layer HRL may include a first material, and the first material may have a higher refractive index than other layers of the window WM. In the window WM, according to an embodiment, at a wavelength of about 550 nm, the refractive index of the first layer HRL may be about 1.7 to about 3.0. At a wavelength of about 550 nm, the refractive index of the first layer HRL may be about 2.0 to about 2.5. At a wavelength of about 550 nm, the refractive index of the first layer HRL may be about 2.10. Due to high refractive characteristics of the first layer HRL, the surface reflectance of the window WM may be decreased. Since the first layer HRL having high refractive characteristics is stacked on the window base layer BL, and the second layer APL and the third layer FL having low refractive index characteristics are stacked in sequence on the first layer HRL, the window WM, according to this embodiment, may have a decreased surface reflectance.

In an embodiment, the first material included in the first layer HRL may include a compound of a first metal oxide and a second metal oxide. The second metal oxide, which is a crystal growth oxide, may promote crystallization of the first metal oxide when the second metal oxide is deposited in the form of a compound with the first metal oxide. Through this, durability of the first layer HRL may be improved. Therefore, the first layer HRL may have high refractive characteristics and excellent mechanical strength. In addition, the second metal oxide may have a lower refractive index than the first metal oxide. The second metal oxide may neutralize a strong red and/or yellow color formed due to the high refractive index characteristics of the first metal oxide, and accordingly, a color shift value of each of color coordinates a* and b* for a reflection color may be close to about 0. That is, reflection color defects of the window WM may be reduced. For example, the first metal oxide may be niobium oxide (Nb₂O₅), and the second metal oxide may be yttrium oxide (Y₂O₃).

In the first layer HRL, the composition ratio of the second metal oxide may be, for example, greater than about 6 weight-percent (wt %) and less than about 10 wt %. More desirably, in the first layer HRL, the composition ratio of the second metal oxide may be about 7 wt % to about 9 wt %. When the composition ratio of the second metal oxide is about 6 wt % or less, the degree of crystallization of the first metal oxide is not sufficient, so that the window WM may have insufficient wear resistance. When the composition ratio of the second metal oxide is about 10 wt % or more, the content of the first metal oxide with high refractive characteristics is reduced, so that the surface reflectance of the window WM may not be sufficiently decreased.

The first layer HRL may have a thickness d2, for example, greater than about 50 nm and less than about 90 nm, or the thickness d2 of the first layer HRL may be about 60 nm to about 80 nm. When the thickness d2 of the first layer HRL is less than about 50 nm, the surface reflectance of the window WM may not be sufficiently decreased. When the thickness d2 of the first layer HRL is about 90 nm or more, the reflection color of the window WM may be affected, and the total thickness may be increased, so that the entire thickness of the display device DD (See FIG. 1A) may be excessively increased.

The first layer HRL may be formed through a thermal evaporation process. In the process of forming the first layer HRL, a deposition film may be formed on a surface of the window base layer BL by applying heat onto a compound of niobium oxide (Nb₂O₅) and yttrium oxide (Y₂O₃) provided in particles (for example, the form of powder). However, an embodiment of the inventive concept is not limited thereto, and the first layer HRL may be formed through various deposition methods. For example, the first layer HRL may be formed through an ion-assisted deposition process. In the process of forming the first layer HRL, a compound of niobium oxide Nb₂O₅ and yttrium oxide Y₂O₃ can be deposited onto the surface of the window base layer BL in the form of particles, and during the deposition process, an ionized argon (Ar) gas or oxygen (O₂) gas is provided together, so that the adhesiveness of the deposition film for the surface of the window base layer BL may be improved.

The first layer HRL may have a single-layer structure. The first layer HRL may be a single layer formed of a compound of the transparent first metal oxide and the transparent second metal oxide. The first layer HRL may not include a plurality of layers.

The second layer APL may be disposed on the first layer HRL, and may be a layer for improving the adhesiveness of the first layer HRL to the third layer FL. The second layer APL may have excellent adhesive properties for each of the first layer HRL and the third layer FL, and may thus be an adhesion promoter for improving interlayer adhesiveness between the first layer HRL and the third layer FL. The second layer APL may be directly disposed on the first layer HRL.

The second layer APL may have excellent mechanical strength while having low refractive index characteristics, and may include a material for improving adhesiveness. The second layer APL may include a second material, and the second material may include a material having a lower refractive index than the material included in the window base layer BL. The second material included in the second layer APL may include at least one of, for example, silica, fused silica, fluorine-doped fused silica, magnesium fluoride (MgF₂), calcium fluoride (CaF₂), aluminum fluoride (AlF₃), yttrium fluoride (YF₃), ytterbium fluoride (YbF₃), aluminum oxide (Al₂O₃), or magnesium oxide (MgO). For example, the second material may include at least one of silicon dioxide (SiO₂) (or silica), magnesium oxide (MgO), or aluminum oxide (Al₂O₃). The second material may include a compound of silicon dioxide (SiO₂) and a third metal oxide, and for example, the third metal oxide may be aluminum oxide (Al₂O₃).

In an embodiment, the second layer APL may have a single-layer structure formed of silicon dioxide (SiO₂). That is, the second layer APL may not include a plurality of layers. At a wavelength of about 550 nm, the second layer APL may have a refractive index of about 1.43.

Alternatively, in an embodiment, the second layer APL may have a single-layer structure formed of a compound of silicon dioxide (SiO₂) and aluminum oxide (Al₂O₃). At a wavelength of about 550 nm, the second layer APL may have a refractive index of about 1.48. When the second layer APL is formed of a compound further containing aluminum oxide (Al₂O₃), compared to the case where the second layer APL is formed of a single material that is silicon dioxide (SiO₂), the second layer APL may have stronger heat resistance and wear resistance while having a similar level of refractive index. Accordingly, the adhesiveness of the second layer APL for surfaces of the first layer HRL and the third layer FL may be further improved, and the durability of the display device DD including the window WM may be improved.

In the compound of silicon dioxide (SiO₂) and aluminum oxide (Al₂O₃) included in the second layer APL, the composition ratio of aluminum oxide (Al₂O₃) may be, for example, about 10 wt % or less. When the composition ratio of aluminum oxide (Al₂O₃) is greater than about 10 wt %, aluminum oxide (Al₂O₃), having a higher refractive index than silicon dioxide (SiO₂), may increase the rate of increase in refractive index of the second layer APL with the increase in aluminum oxide (Al₂O₃) content, and thus the reflectance of the window WM may increase.

The second layer APL, like the first layer HRL, may be formed through a thermal evaporation process. However, an embodiment of the inventive concept is not limited thereto, and the second layer APL may also be formed through an ion-assisted deposition process.

At a wavelength of about 550 nm, the refractive index of the second layer APL may be about 1.3 to about 1.6. In the window WM according to an embodiment, the refractive index of the second layer APL may be about 1.4 to about 1.5 at a wavelength of about 550 nm. Since the refractive index of the second layer APL satisfies the range at a wavelength of about 550 nm, the surface reflectance of the window WM may be decreased.

The second layer APL may have a thickness d3 of about 10 nm to about 100 nm. When the thickness d3 of the second layer APL is less than about 10 nm, improvement effect of the adhesiveness between the first layer HRL and the second layer APL may not be achieved, and the mechanical strength of the window WM may be reduced. When the thickness d3 of the second layer APL is greater than about 100 nm, the reflectance of the window WM may increase, and the total thickness of the window WM may increase, thereby excessively increasing the entire thickness of the display device DD.

The third layer FL may be disposed on the second layer APL, and may be a layer for improving slippiness, scratch resistance, and the like of a surface of the window WM. In an embodiment, the third layer FL may be an anti-fingerprint layer that has excellent fingerprint resistance and inhibits surface wear. The third layer FL may be directly disposed on the second layer APL, where the third layer FL may be the uppermost layer of the window WM, and an upper surface of the third layer FL may define the outermost surface (that is, the uppermost surface) of the window WM.

The third layer FL may include a material excellent in scratch resistance and slippiness and having low refractive characteristics. The third layer FL may include a third material, and the third material may include a material having a lower refractive index than the material included in the second layer APL. In an embodiment, the third material included in the third layer FL may include a fluorine-containing polymer. The third material may include, for example, a perfluoropolyether (PFPE) compound. The third material may include perfluoropolyether silane, perfluoroalkyl ether alkoxysilane, perfluoroalkyl ether co-polymer, or the like. Since the third layer FL includes a perfluoropolyether compound, the fingerprint resistance and the scratch resistance of the third layer FL may be improved.

At a wavelength of about 550 nm, the third layer FL may have a refractive index of about 1.3 to about 1.5. In the window WM according to an embodiment, the refractive index of the third layer FL may be about 1.30 to about 1.35 at a wavelength of about 550 nm. Since the refractive index of the third layer FL satisfies the range at a wavelength of about 550 nm, the surface reflectance of the window WM may be decreased.

The third layer FL may have a thickness d4 of, for example, about 20 nm to about 45 nm. When the thickness d4 of the third layer FL is less than about 20 nm, the fingerprint resistance and the scratch resistance of the window WM may be reduced. When the thickness d4 of the third layer FL is greater than about 45 nm, the reflectance of the window WM may increase, and the total thickness of the window WM may increase, thereby excessively increasing the entire thickness of the display device.

In the window WM according to an embodiment, the double-sided reflectance of a surface of the window WM may be about 5.0% or less at a wavelength of about 550 nm. The third layer FL may be the uppermost layer of the window WM according to an embodiment, and the reflectance at an upper surface of the third layer FL may be about 1.0% or less. In the window WM according to an embodiment, the single-sided reflectance of a surface of the window WM coated on the window base layer BL may be about 1.0% or less at a wavelength of about 550 nm. Meanwhile, in this specification, the “reflectance” of the window WM is defined as the ratio of light reflected to the outside versus light incident to the inside of the window WM. The light reflected to the outside includes both of specular reflection light, which is light reflected at the same angle after being incident, and diffuse reflection light which is scattered and reflected in different directions. That is, in this specification, the reflectance is defined as a specular component included (SCI) reflectance.

Referring to FIGS. 1B, 3, and 4A together, like in the display device DD according to an embodiment, in the case where the anti-reflection layer 300 included in the display module DM includes a plurality of color filters 320, display efficiency may be further improved than in the case where a polarization layer is included, but the reflectance may be increased. In the display device DD according to an embodiment of the inventive concept, since the window WM includes the first metal oxide having a high refractive index, the surface reflectance of the window WM may be decreased. In the display device DD according to an embodiment, although the reflectance inside the display module DM may be about 2.0% at a wavelength of about 550 nm, the surface reflectance of the window WM according to an embodiment may be about 1.0% or less at a wavelength of about 550 nm, and thus the reflectance of the display device DD may be about 3.0% or less.

Moreover, in the display device DD according to an embodiment of the inventive concept, since the window WM includes a compound of the first metal oxide and the second metal oxide that promotes crystallization of the first metal oxide and that has a lower refractive index than the first metal oxide, the degree of reflection color shift may be reduced, and the mechanical strength such as wear resistance and abrasion resistance may be improved. Accordingly, the reflectance of the entire display device DD may be maintained to be low, and at the same time, reflection color defects of the display device DD may be prevented, thereby improving the durability and reliability of the display device DD.

Referring to FIG. 4B, a window WM-1 according to an embodiment of the inventive concept may further include a fourth layer RCL disposed between a window base layer BL and a first layer HRL.

The fourth layer RCL may be disposed on the window base layer BL, and may be a layer for improving adhesiveness of the window base layer BL to the first layer HRL. The fourth layer RCL may have excellent adhesiveness for each of the window base layer BL and the first layer HRL, and may thus serve as an adhesion promoter for improving interlayer adhesiveness between the window base layer BL and the first layer HRL. In addition, the fourth layer RCL may be a layer that is bonded to the base layer for providing an excellent reflection color. The fourth layer RCL may be directly disposed on the window base layer BL. The fourth layer RCL may be in contact with the window base layer BL and the first layer HRL.

The fourth layer RCL may have excellent mechanical strength while having low refractive characteristics, and may include a material for improving adhesiveness. The fourth layer RCL may include a fourth material, and the fourth material may include a material having a lower refractive index than the materials included in the window base layer BL and the first layer HRL.

The fourth material included in the fourth layer RCL may include at least one of, for example, silica, fused silica, fluorine-doped fused silica, magnesium fluoride (MgF₂), calcium fluoride (CaF₂), aluminum fluoride (AlF₃), yttrium fluoride (YF₃), ytterbium fluoride (YbF₃), aluminum oxide (Al₂O₃), or magnesium oxide (MgO). For example, the fourth layer RCL may include at least one of silicon dioxide (SiO₂) (or silica), magnesium oxide (MgO), or aluminum oxide (Al₂O₃). The fourth layer RCL may be formed through a thermal evaporation process or an ion-assisted deposition process.

In an embodiment, the fourth layer RCL may have a single-layer structure formed of silicon dioxide (SiO₂). That is, the fourth layer RCL may not include a plurality of layers.

The fourth layer RCL may have a thickness d5 of, for example, about 10 nm to about 25 nm. When the thickness d5 of the fourth layer RCL is less than about 10 nm, improvement effect of adhesiveness between the window base layer BL and the first layer HRL may not be achieved, and the mechanical strength of the window WM-1 may be reduced. When the thickness d5 of the fourth layer RCL is greater than about 25 nm, the reflectance of the window WM-1 may increase, and the total thickness of the window WM-1 may increase, thereby excessively increasing the entire thickness of the display device DD (see FIG. 1A).

At a wavelength of about 550 nm, the fourth layer RCL may have a refractive index of about 1.3 to about 1.6. In the window WM-1 according to an embodiment, the refractive index of the fourth layer RCL may be about 1.4 to about 1.5 at a wavelength of about 550 nm. Since the refractive index of the fourth layer RCL satisfies the range at a wavelength of about 550 nm, the surface reflectance of the window WM-1 may be decreased.

Since the window WM-1 according to an embodiment of the inventive concept further includes the fourth layer RCL bonded to the window base layer BL and the first layer HRL, it may be possible to have more excellent adhesiveness between the window base layer BL and the first layer HRL, and to have more excellent reflection color.

Table 1 below shows evaluation results of the surface reflectance, reflection color, and wear resistance of each of a window in Example and windows in Comparative Examples. In Table 1, the window in Example is a window having a structure in which the fourth layer, the first layer, the second layer, and the third layer are stacked in sequence on the base layer as described with reference to FIG. 4B. In the window of Example, the base layer is formed of a glass substrate, the fourth layer is formed of silicon dioxide (SiO₂) with a thickness of about 13.19 nm, the first layer is formed of a compound of niobium oxide (Nb₂O₅) and yttrium oxide (Y₂O₃) with a thickness of about 70 nm, the second layer is formed of a compound of silicon dioxide (SiO₂) and aluminum oxide (Al₂O₃) with a thickness of about 45 nm, and the third layer is formed of perfluoropolyether (PFPE) with a thickness of about 25 nm.

A window in Comparative Example 1 has a structure of first to third comparative layers stacked in sequence on a base layer. The base layer is formed of a glass substrate, the first comparative layer is formed of magnesium fluoride (MgF₂) with a thickness of about 80 nm, the second comparative layer is formed of silicon dioxide (SiO₂) with a thickness of about 10 nm, and the third comparative layer is formed of perfluoropolyether (PFPE) with a thickness of about 20 nm. That is, the window in Comparative Example 1, unlike the window in Example, is characterized by including magnesium fluoride (MgF₂) for low reflection characteristics.

A window in Comparative Example 2 has a structure of fourth to eighth comparative layers stacked in sequence on a base layer. The base layer is formed of a glass substrate, the fourth comparative layer is formed of silicon dioxide (SiO₂) with a thickness of about 13.19 nm, the fifth comparative layer is formed of yttrium oxide Y₂O₃ with a thickness of about 103.60 nm, the sixth comparative layer is formed of niobium oxide (Nb₂O₅) with a thickness of about 13.64 nm, the seventh comparative layer is formed of silicon dioxide (SiO₂) with a thickness of about 99.25 nm, and the eighth comparative layer is formed of perfluoropolyether (PFPE) with a thickness of about 25 nm. That is, the window in Comparative Example 2, unlike the window in Example, includes a layer including niobium oxide (Nb₂O₅) and a layer including yttrium oxide (Y₂O₃) formed independently of each other. In addition, an adhesion promoter, disposed between the layer including niobium oxide (Nb₂O₅) and the layer including perfluoropolyether (PFPE), is formed of a single material that is silicon dioxide (SiO₂) in the window of Comparative Example 2 while in the window of Example the adhesion promoter is formed of an oxide of silicon dioxide (SiO₂) and aluminum oxide Al₂O₃.

In Table 1, the surface reflectance is presented by measuring a double-sided reflectance (%) and a single-sided reflectance (%), and the single-sided reflectance (%) refers to a reflectance of a coated surface. In Table 1, the reflection color is presented by measuring a color shift value of each of color coordinates a* and b* with respect to specular component excluded reflection. In Table 1, for evaluation of wear resistance, an initial contact angle of a surface of the window is measured and compared to a contact angle of a surface of the window measured after the surface has been rubbed about 3000 times with an industrial eraser.

TABLE 1

| | | | | | | Wear resistance | |
|---|---|---|---|---|---|---|---|
| | | Surface reflectance | | | | (eraser) test | |
| | | Double-sided | Single-sided | Reflection | | Initial | Contact angle (°) |
| | Evaluation | reflectance | reflectance | color (SCE) | | contact | after rubbed with |
| Classification | method | (%) | (%) | a* | b* | angle (°) | eraser 3000 times |
| Comparative | Sample test | 5.94 | 1.94 | −0.05 | −0.33 | 116.4 | 85.9 |
| Example 1 | | | | | | | |
| Comparative | Simulation | 4.80 | 0.80 | −1.46 | −0.92 | | |
| Example 2 | test | | | | | | |
| | Sample test | 4.75 | 0.75 | 0.85 | −1.11 | 115.2 | 105.1 |
| Example | Simulation | 4.89 | 0.89 | −0.28 | −0.36 | | |
| | test | | | | | | |
| | Sample test | 4.80 | 0.80 | 0.17 | −0.21 | 117.1 | 111.8 |

Referring to the results shown in Table 1, in each of Comparative Example 2 and Example, the double-sided reflectance and the single-sided reflectance are higher than in Comparative Example 1. Through this, it may be seen that the surface reflectance of the window is decreased when the window includes niobium oxide (Nb₂O₅), versus when including magnesium fluoride (MgF₂). It may be seen that each of the window in Comparative Example 2 and the window in Example has a single-sided reflectance of about 1.0% or less, and has a double-sided reflectance of about 5.0% or less.

It may be seen that Example has a lower color shift value than Comparative Example 2 in a reflection color evaluation. Through this, it may be seen that reflection color defects of the window are reduced when the window is formed of a single layer including a compound of niobium oxide (Nb₂O₅) and yttrium oxide (Y₂O₃), versus when having a layer including niobium oxide (Nb₂O₅) and a layer including yttrium oxide (Y₂O₃) formed independently of each other.

It may be seen that in each of Comparative Example 1 and Example, the degree to which the contact angle is reduced compared to the initial contact angle is further reduced than in Comparative Example 2 after the wear resistance evaluation has been processed. Through this, it may be seen that the wear resistance is improved when the window includes niobium oxide (Nb₂O₅), versus when including magnesium fluoride (MgF₂).

In addition, it may be seen that in Example, the degree to which the contact angle is reduced compared to the initial contact angle is further reduced than in Comparative Example 1 after the wear resistance evaluation has been processed. It may be seen that the wear resistance is improved when a single layer including a compound of niobium oxide (Nb₂O₅) and yttrium oxide (Y₂O₃) is provided to the window, and an adhesion promoter, including a compound of silicon dioxide (SiO₂) and aluminum oxide (Al₂O₃), is provided between a layer including niobium oxide (Nb₂O₅) and a layer including perfluoropolyether (PFPE), versus when a layer including niobium oxide (Nb₂O₅) and a layer including yttrium oxide (Y₂O₃) are provided to the window independently of each other, and an adhesion promoter including a single material that is silicon dioxide (SiO₂) is provided between a layer including niobium oxide (Nb₂O₅) and a layer including perfluoropolyether (PFPE).

Through the results shown in Table 1, it may be seen that since the window according to an embodiment includes a first layer containing a compound of niobium oxide (Nb₂O₅) and yttrium oxide (Y₂O₃) and a second layer containing a compound of silicon dioxide (SiO₂) and aluminum oxide (Al₂O₃), the window has improved wear resistance while having a low surface reflectance and not having reflection color defects.

Table 2 below shows the surface reflectance and reflection color of the window according to an embodiment, and Table 3 shows the surface reflectance and evaluation results of wear resistance and abrasion resistance in the window according to an embodiment. In case of Example in Table 2, the double-sided reflectance and the reflection color are measured for windows having the stacked structure of Example previously described with reference to Table 1, but of five specifications with different thicknesses of the first layer, and with the same thickness applied for the other layer as what has been previously described with reference to Table 1. In case of Example in Table 3, the double-sided reflectance and evaluation results of wear resistance and abrasion resistance are measured for windows having the stacked structure of Example previously described with reference to Table 1, but of six specifications with different composition ratios of a second metal oxide in the first layer. In Table 3, the wear resistance evaluation is processed as what has been previously described with reference to Table 1, and the abrasion resistance evaluation is performed such that an initial contact angle of a surface of the window is measured, and compared to a contact angle of the surface of the window measured after the surface has been rubbed about 3000 times using a steel-wool.

TABLE 2

| | Thickness | double-sided | | |
|---|---|---|---|---|
| Example | of first layer | reflectance | Reflection color (SCE) | |
| Specification | (nm) | (%) | a* | b* |
| 1 | 50 | 5.24 | +1.25 | −0.03 |
| 2 | 60 | 4.98 | +1.06 | −0.15 |
| 3 | 70 | 4.80 | +0.17 | −0.21 |
| 4 | 80 | 4.89 | +0.27 | −1.46 |
| 5 | 90 | 4.92 | +0.41 | −1.61 |

TABLE 3

| | | | Wear resistance (eraser) test | |
|---|---|---|---|---|
| | Composition | | Contact angle | Contact angle |
| | ratio of | double- | after rubbed | after rubbed |
| | second metal | sided | with eraser | with steel- |
| Example | oxide in first | reflectance | 3000 | wool 3000 |
| Specification | layer (wt %) | (%) | times (°) | times (°) |
| 6 | 5 | 4.54 | 93 | 82 |
| 7 | 6 | 4.61 | 101 | 92 |
| 8 | 7 | 4.75 | 104 | 101 |
| 9 | 8 | 4.89 | 107 | 105 |
| 10 | 9 | 4.92 | 109 | 107 |
| 11 | 10 | 5.11 | 109 | 110 |

Referring to the results shown in Table 2, it may be seen that Example Specification 1 has a high double-sided reflectance greater than about 5.0%. That is, it may be seen that when the second layer has a thickness of about 50 nm or less, the surface reflectance of the window is not sufficiently decreased.

It may be seen that Example Specification 5 has a high color shift value in the reflection color evaluation as it has a b* value less than about −1.5. That is, it may be seen that when the second layer has a thickness of about 90 nm or more, the reflection color defects may occur.

Therefore, it may be seen that the window according to an embodiment may be reduced in reflection color defects, while having a low surface reflectance, when the second layer has a thickness greater than about 50 nm and less than about 90 nm, and more desirably, a thickness of about 60 nm to about 80 nm.

Referring to the results shown in Table 3, it may be seen that Example Specification 6 has a contact angle less than about 95° in each of wear resistance and abrasion resistance evaluations. It may be seen that Example Specification 7 has a contact angle less than about 95° in the abrasion resistance evaluation. That is, it may be seen that when the content of yttrium oxide (Y₂O₃) in the second layer is about 6 wt % or less, the crystallization rate of niobium oxide (Nb₂O₅) is insufficient, and thus the wear resistance or abrasion resistance may not be improved.

It may be seen that Example Specification 11 has a high double-sided reflectance greater than about 5.0%. That is, when the content of yttrium oxide (Y₂O₃) in the second layer is about 10 wt % or more, the surface reflectance of the window is not sufficiently decreased.

Therefore, it may be seen that when the content of yttrium oxide Y₂O₃ in the second layer is greater than about 6 wt % and less than about 10 wt %, and more desirably, about 7 wt % to about 9 wt %, the window according to an embodiment is improved both in wear resistance and abrasion resistance while having a low surface reflectance, and thus the durability and reliability may be improved.

According to an embodiment of the inventive concept, a window may include a plurality of layers disposed on a base layer and containing particular materials, and may thus be reduced in reflection color defects while having low refractive characteristics, and have excellent interlayer adhesiveness and improved mechanical strength such as wear resistance and abrasion resistance. Accordingly, a display device including the window may have improved durability and reliability.

Although the embodiments of the inventive concept have been described, it is understood that the inventive concept should not be limited to these embodiments but various changes and modifications can be made by one ordinary skilled in the art within the spirit and scope of the inventive concept as hereinafter claimed. Therefore, the technical scope of the inventive concept should not be limited to the contents described in the detailed description of the specification, but should be defined by the claims.

What is claimed is:

1. A window comprising:
a window base layer;
a first layer disposed on the window base layer;
a second layer disposed on the first layer; and
a third layer disposed on the second layer,
wherein the first layer includes a compound of a first metal oxide and a second metal oxide.

2. The window of claim 1, wherein the second metal oxide has a refractive index less than the refractive index of the first metal oxide, and
a content of the second metal oxide is greater than about 6 wt % and less than about 10 wt %.

3. The window of claim 1, wherein the first layer has a thickness greater than about 50 nm and less than about 90 nm.

4. The window of claim 1, wherein the first metal oxide is niobium oxide (Nb₂O₅), and
the second metal oxide is yttrium oxide (Y₂O₃).

5. The window of claim 1, wherein the first layer has a refractive index greater than that of each of the base layer and the second layer, and the refractive index of the first layer is about 1.7 to about 3.0 at a wavelength of about 550 nm.

6. The window of claim 1, wherein the second layer comprises at least one of silicon dioxide (SiO₂), fused silica, fluorine-doped fused silica, magnesium fluoride (MgF₂), calcium fluoride (CaF₂), aluminum fluoride (AlF₃), yttrium fluoride (YF₃), ytterbium fluoride (YbF₃), aluminum oxide (Al₂O₃), or magnesium oxide (MgO).

7. The window of claim 1, wherein the second layer comprises a compound of silicon dioxide (SiO₂) and a third metal oxide.

8. The window of claim 7, wherein the third metal oxide comprises aluminum oxide (Al₂O₃), and
a content of the third metal oxide is about 10 wt % or less.

9. The window of claim 1, wherein the third layer comprises a fluorine-containing polymer.

10. The window of claim 1, wherein the second layer has a refractive index of about 1.3 to about 1.6 at a wavelength of about 550 nm, and
the third layer has a refractive index of about 1.3 to about 1.5 at a wavelength of about 550 nm.

11. The window of claim 1, wherein the second layer has a thickness of about 10 nm to about 100 nm, and
the third layer has a thickness of about 20 nm to about 45 nm.

12. The window of claim 1, wherein the base layer comprises a glass substrate or a polymer film.

13. The window of claim 1, wherein the second layer is directly disposed on the first layer, and
the third layer is directly disposed on the second layer.

14. The window of claim 1, wherein a reflectance at an upper surface of the third layer is about 1.0% or less at a wavelength of about 550 nm.

15. The window of claim 1, further comprising a fourth layer disposed between the base layer and the first layer, and including at least one of silicon dioxide (SiO₂), fused silica, fluorine-doped fused silica, magnesium fluoride (MgF₂), calcium fluoride (CaF₂), aluminum fluoride (AlF₃), yttrium fluoride (YF₃), ytterbium fluoride (YbF₃), aluminum oxide (Al₂O₃), or magnesium oxide (MgO).

16. A display device comprising
a display module, and
a window disposed on the display module,
wherein the window includes:
a base layer;
a first layer disposed on the base layer;
a second layer disposed on the first layer; and
a third layer disposed on the second layer,
the first layer containing a compound of a first metal oxide and a second metal oxide.

17. The display device of claim 16, wherein the first metal oxide is niobium oxide (Nb₂O₅), and
the second metal oxide is yttrium oxide (Y₂O₃).

18. The display device of claim 16, wherein the second layer comprises a compound of silicon dioxide (SiO₂) and aluminum oxide (Al₂O₃).

19. The display device of claim 16, wherein the display module comprises:
a base substrate;
a circuit layer disposed on the base substrate;
a light-emitting element layer including a light-emitting element, and disposed on the circuit layer; and
an anti-reflection layer including a color filter overlapping the light-emitting element, and disposed on the light-emitting element layer.

20. The display device of claim 16, wherein an upper surface of the third layer defines an outermost surface of the window.
